(19) United States
(12) Patent Application Publication
(10) Pub. No.: US 2023/0298989 A1
(43) Pub. Date: Sep. 21, 2023

(54) CHIP-INTERCONNECT ARRANGEMENT, METHOD FOR FORMING A CHIP-INTERCONNECT ARRANGEMENT, DOCUMENT STRUCTURE AND METHOD FOR FORMING A DOCUMENT STRUCTURE

(71) Applicant: Infineon Technologies AG, Neubiberg (DE)

(72) Inventors: Jens Pohl, Bernhardswald (DE); Frank Püschner, Kelheim (DE); Thomas Spöttl, Mintraching (DE); Uwe Wagner, Abbach (DE)

(21) Appl. No.: 18/182,476

(22) Filed: Mar. 13, 2023

(30) Foreign Application Priority Data
Mar. 15, 2022 (DE) 102022106022.5

(51) Int. Cl. H01L 23/498; H01L 23/485; H01L 21/56; H01L 23/66; G06K 19/077

(52) U.S. Cl. CPC H01L 23/49855; H01L 23/485; H01L 21/56; H01L 23/66; G06K 19/07722; H01L 2223/6677

(57) ABSTRACT

A chip-interconnect arrangement including a substrate having a cavity, a chip having at least one chip contact and one chip contact surface, the chip being arranged in the cavity, an interconnect having an interconnect surface, the interconnect being applied on a surface of the substrate, and an electrically conductive adhesion medium, which electrically connects the at least one chip contact to the interconnect, wherein the interconnect surface is planar.

### TECHNICAL FIELD

The disclosure relates to a chip-interconnect arrangement, a method for forming a chip-interconnect arrangement, a document structure and a method for forming a document structure.

### BACKGROUND

For various applications, such as for example (e.g. crypto-) banknotes, documents, etc., it is desirable to embed a chip in paper layers.

The chip should be able to provide contactless communication, for example as near field communication (NFC), for example as a passive element that receives energy by means of near field communication, e.g. from a smartphone, and—depending on the planned use—should be configured to implement application-related functions, e.g. to sign transactions (e.g. by means of elliptic curve cryptography, e.g. a so-called Elliptic Curve Digital Signature Algorithm (ECDSA)).

Furthermore, present-day chip arrangements are typically too thick or their design means that they are not robust enough, with the result that they are damaged and fail electrically during the manufacturing process or during later use.

Assuming a conventional banknote having a thickness of between approximately 90 μm and 110 μm, and assuming that two layers of paper, each approximately 35 μm thick, should be present for providing the banknote functionality (e.g. for securing/holding the chip and in order to hamper or prevent mechanical manipulation), this leaves between 20 μm and 40 μm for a layer in which the chip having the described functionality is to be accommodated, possibly somewhat more, for example up to approximately 70 μm or at least significantly thinner than 100 μm, if a somewhat thicker banknote is acceptable.

The chip itself is typically too small to accommodate an antenna suitable for NFC directly on the chip, rather it might be necessary to arrange the antenna on a substrate on/in which the chip is arranged and is connected to the antenna.

However, standard connection technologies such as wire bonding or a flip-chip connection are not suitable because they result in an excessively large thickness of the chip arrangement.

Wire bonding, for example, requires a minimum height of the wire arc that is encapsulated (“Glob top”), flip-chip is unattractive because it requires connections in a cavity of a substrate, which makes the substrate complex and expensive to manufacture, and solders would have to be able to bridge gaps of approximately 200 μm to 300 μm between adjacent contacts, which is not possible owing to the surface tension of the solder during melting (the solder would instead accumulate at both contacts, without bridging the gap).

When conductive pastes, e.g. conductive adhesives, are used, they are typically applied, for example by dispensing under time/pressure control by means of needles or by printing by means of inkjet or stencil printing. This procedure also results in the chip arrangement becoming too thick. This is because the thickness of the paste layer is typically determined by material properties such as thixotropic properties, for example, which have the effect that the connection material typically extends over the connecting surfaces significantly upward in height. That has the consequence that chip arrangements that are manufactured in accordance with the prior art using conductive pastes are too thick for use in banknotes and other (paper) documents.

### SUMMARY

In various exemplary aspects, a chip arrangement is provided in which a connection structure between a chip and an interconnect (which can comprise an antenna, for example) is made so thin or flat that the chip arrangement is usable in a banknote or a comparably thin (paper) document.

The connection structure can comprise an isotropic conductive material, for example a conductive paste or a conductive adhesion medium. After having been applied, the conductive material can be reshaped to a smaller height (or thickness), for example can be pressed flat, for example by means of a hot thermode.

After the reshaping, the reshaped conductive material can comprise a planar surface.

Furthermore, the conductive material can form an electrically conducting contact between a chip contact and the interconnect (e.g. a contact of the antenna). The conductive material can furthermore be coplanar with respective surfaces of the contacts (also referred to as terminals), or it can extend only insignificantly beyond the lower surfaces (as viewed from the substrate), for example by maximally 10 μm or maximally 5 μm.

In various exemplary aspects, the reshaped conductive material can be coplanar with that surface (chip contact surface or interconnect surface) which is further away from a central plane of the chip-interconnect arrangement (which can be parallel to a principal plane of the substrate), i.e. with the surface situated at a higher level, and can at least partly cover the other surface (i.e. the surface situated at a lower level, or lower surface).

In various exemplary aspects, a chip-interconnect arrangement is provided, comprising a substrate having a cavity, a chip having at least one chip contact and one chip contact surface, such chip being arranged in the cavity, an interconnect having an interconnect surface, said interconnect being applied on a surface of the substrate, and an electrically conductive adhesion medium, which electrically connects the at least one chip contact to the interconnect, wherein the surface of the adhesion medium is planar.

Optionally, the chip contact surface, the interconnect surface and a surface of the adhesion medium are coplanar with respect to one another or the adhesion medium is coplanar with respect to that surface out of the chip contact surface and the interconnect surface which is further away from a principal plane of the substrate.

### BRIEF DESCRIPTION OF THE DRAWINGS

Exemplary aspects of the disclosure are illustrated in the Figures and are explained in greater detail below.

In the Figures:

FIG. 1A shows a schematic illustration of a chip for use in the case of a chip-interconnect arrangement in accordance with various exemplary aspects:

FIG. 1B shows a schematic illustration of a substrate with an interconnect for use in the case of a chip-interconnect arrangement in accordance with various exemplary aspects;

FIG. 2A to 2E show an elucidation of a method for forming a chip-interconnect arrangement in accordance with various exemplary aspects;

FIG. 3A to 3D show schematic detail views of chip-interconnect arrangements in accordance with various exemplary aspects;

FIG. 4A to 4C show an elucidation of a method for forming a chip-interconnect arrangement in accordance with various exemplary aspects;

FIG. 5 shows schematic detail views of a process for producing chip-interconnect arrangements in accordance with various exemplary aspects;

FIG. 6A shows an exploded drawing of a document structure in accordance with various exemplary aspects;

FIG. 6B shows a schematic illustration of a document structure in accordance with various exemplary aspects;

FIG. 7 shows a flow diagram of a method for forming a chip-interconnect arrangement in accordance with various exemplary aspects; and

FIG. 8 shows a flow diagram of a method for forming a document structure in accordance with various exemplary aspects.

### DETAILED DESCRIPTION

In the following detailed description, reference is made to the accompanying drawings, which form part of this description and show for illustration purposes specific aspects in which the subject matter of the disclosure can be implemented. In this regard, direction terminology such as, for instance, “at the top”, “at the bottom”, “at the front”, “at the back”, “front”, “rear”, etc. is used with respect to the orientation of the figure(s) described. Since components of aspects can be positioned in a number of different orientations, the direction terminology serves for elucidation and is not restrictive in any way whatsoever. It goes without saying that other aspects can be used and structural or logical changes can be made, without departing from the scope of protection of the subject matter of the present disclosure. It goes without saying that the features of the various exemplary aspects described herein can be combined with one another, unless specifically indicated otherwise. Therefore, the following detailed description should not be interpreted in a restrictive sense, and the scope of protection of the subject matter of the present disclosure is defined by the appended claims.

In the context of this description the terms “connected”, “attached” and “coupled” are used to describe both a direct and an indirect connection, a direct or indirect attachment and a direct or indirect coupling. In the figures, identical or similar elements are provided with identical reference signs, insofar as this is expedient.

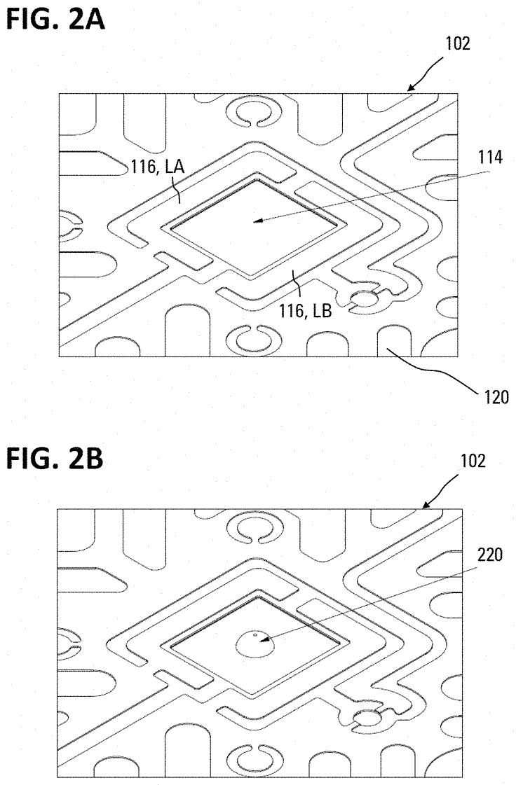

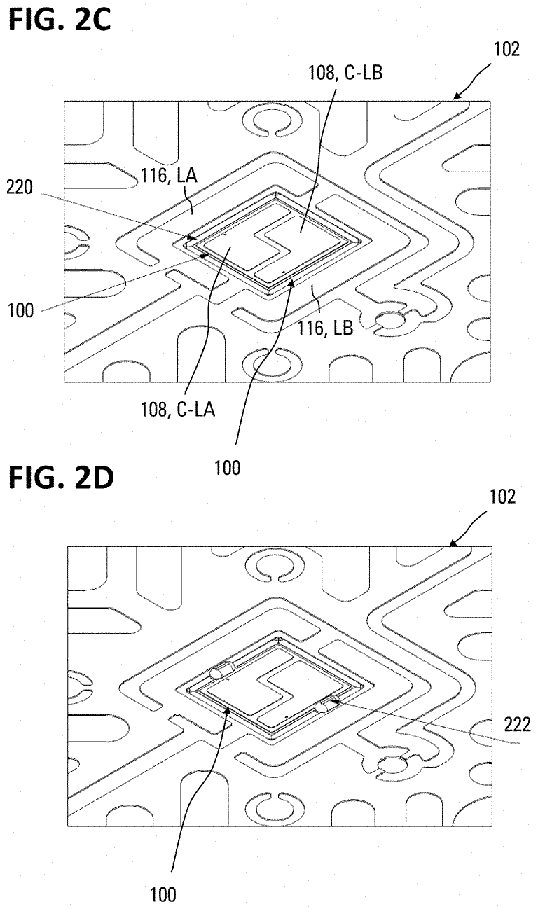

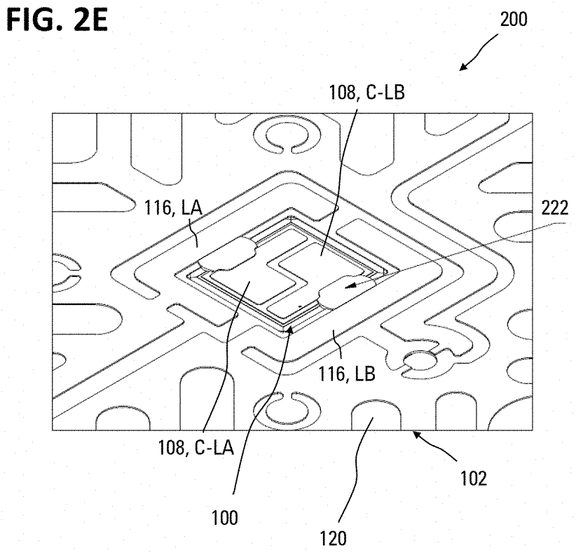

FIGS. 2A to 2E elucidate a method for forming a chip-interconnect arrangement 200 in accordance with various exemplary aspects. The method is typically embodied as a roll-to-roll method using a 35 mm tape that is typical for smart card modules. For the sake of simplicity, only a single module is illustrated here in each case.

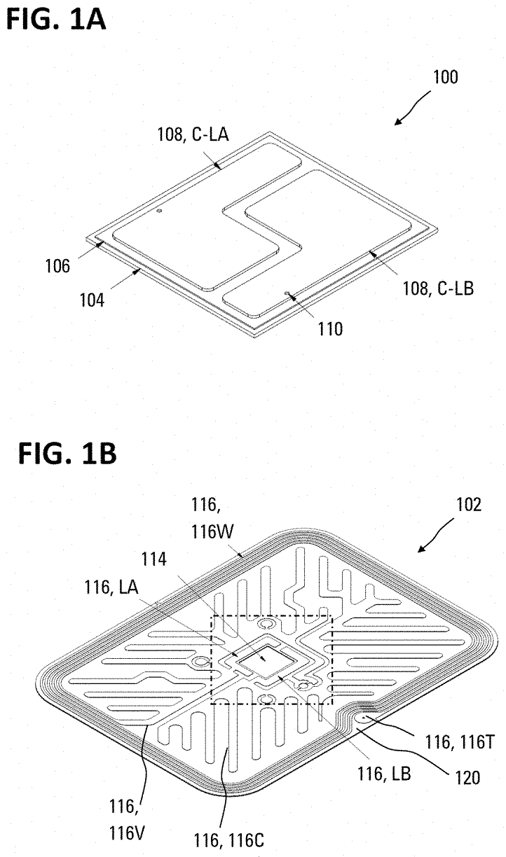

In the method, a chip 100 is inserted into a cavity 114 of an interconnect arrangement 102. In order to avoid a lack of clarity in figures which serve to elucidate the method or properties of the chip-interconnect arrangement 200 in accordance with various exemplary aspects, FIG. 1A illustrates an exemplary chip 100 and FIG. 1B illustrates an exemplary interconnect arrangement 102, which can each be part of the chip-interconnect arrangement 200 in accordance with various exemplary aspects, with comprehensive reference signs. Some of the reference signs are omitted in the subsequent figures. If appropriate, FIG. 1A and/or FIG. 1B can be consulted therefor.

The chip-interconnect arrangement 200 can comprise a substrate 120 having a cavity 114. Such a substrate 120 is illustrated by way of example in FIG. 2A.

An interconnect 116 can be applied on at least one surface of the substrate 120. The interconnect can form for example a so-called Coil-on-Module antenna (CoM antenna) for contactless (CL) communication. The interconnect 116 can be arranged as a structured metallization on the substrate 120. In various exemplary aspects, the interconnect 116 can comprise a plurality of functional regions or at least some of them, for example antenna windings 116W, terminal contacts LA and LB (also referred to antenna contacts, contacts of the antenna, terminals or antenna terminals), connection structures 116V, capacitive structures 116C and through contacts 116T. In various exemplary aspects, the interconnect (e.g. the antenna) can be embodied on both mutually opposite main surfaces of the substrate 120. By way of example, the antenna windings 116W can be arranged on both main surfaces, and/or the capacitive structures 116C can be arranged on both main surfaces such that they jointly form a capacitor. A connection between the two main surfaces can be provided by means of the through contacts 116T. The arrangement of the antenna 116 over both main surfaces of the substrate 120 can be affected for example as in DE 10 2018 105 383 B4.

The interconnect 116 can comprise an interconnect surface. The latter should be understood to mean a topmost surface of the interconnect 116, i.e. that surface of the interconnect 116 which is the furthest away from the substrate 120 and faces away from the latter. Surfaces of the interconnect 116 which are situated between the interconnect surface and the substrate 120 are referred to as side surfaces.

The substrate 120 having the cavity 114 and the interconnect 116 can jointly form the interconnect arrangement 102.

The chip-interconnect arrangement 200 can comprise a chip 100 arranged in the cavity 114.

The chip 100 can be for example a security chip, for example a so-called secure element. The chip 100 can be configured for example to sign transactions (e.g. by means of ECDSA), to verify an authenticity of a document into which the chip-interconnect arrangement 200 can be embodied (i.e. to authenticate the document), and/or to store a blockchain or information related thereto.

The chip 100 can comprise a very thin semiconductor (e.g. silicon) substrate 104. The thickness of the substrate 104 can be for example in a range of approximately 15 μm to approximately 40 μm, for example of approximately 15 μm to approximately 30 μm.

The chip 100 can comprise at least one chip contact 108, which can be connected to a circuit of the chip 100 by means of a via (or at least one via per chip contact 108 in the case of a plurality of chip contacts 108).

A passivation layer 106, which can comprise a polyimide or some other customary passivation material, for example, can be arranged between the at least one chip contact 108 and the substrate 104.

The at least one chip contact 108 can be part of a redistribution layer plane (RDL), which is applied at the wafer level and can serve the purpose of providing chip terminals of the interconnect 116.

The redistribution layer plane—and thus the at least one chip contact 108—typically comprises a so-called seed layer, which can comprise for example a very thin (compared with the subsequent electrolytic layer) Ti or TiW layer with sputtered Cu, and copper deposited electrolytically thereon, typically with a thickness in a range of approximately 3 μm to approximately 30 μm, nickel (typically approximately 500 nm to approximately 5 μm) and a topmost thin Au or Pd layer (of typically approximately 50 nm to approximately 150 nm).

Depending on the exact processes implemented at the wafer level, the side surfaces of the chip contacts 108 can be covered by the topmost layer (i.e. for example by Ni+Au/Ni+Pd), or the copper can be exposed at the side surfaces, and only the surface can be covered by the topmost layer.

If the copper is exposed at the side surfaces, that can possibly necessitate an additional (pre-)treatment—in particular prior to contacting the chip contacts 108—, e.g. applying a protective layer such as, for example, an organic surface protection (OSP) or, for example, removing copper oxide e.g. by means of a plasma process.

In various exemplary aspects, the chip 100 can comprise two chip contacts 108, which can be formed in polygonal fashion, for example in L-shaped fashion, and can be arranged in an interleaved manner. In various exemplary aspects, an angle between the long limb and the short limb can comprise 90° or a different angle than that (larger or smaller). In various exemplary aspects, the long limbs can be arranged along opposite chip edges, and the short limbs can likewise be arranged along opposite chip edges. In other exemplary aspects, the limbs can extend at a different angle (differently than parallel) to the chip edge, for example at an angle of between 0° and 45°, which can be governed for example by the crystal structure of the semiconductor material of the substrate 104.

The two chip contacts 108 can jointly cover almost the entire chip area. As a result of this and owing to the interleaved arrangement of the L-shaped contacts, a mechanical stability of the thin chip 100 can be increased since the thin silicone can thus be protected against mechanical stresses along two orthogonal directions.

In order to indicate the connection for which the two chip contacts 108 from the exemplary aspects are available, they are additionally designated by C-LA (for the contact with the terminal LA) and C-LB (for the contact with the terminal LB), in the figures.

The chip contact 108 can comprise a chip contact surface. The chip contact surface should be understood as the topmost surface of the chip contact 108, i.e. that surface which is the furthest away from a chip substrate 104 and faces away from the latter.

The chip 100 can be or have been arranged in the cavity 114 such that its at least one chip contact 108 faces away from the cavity 114. To put it another way, the at least one chip contact 108 is exposed when the chip 100 is arranged in the cavity 114.

For the purpose of arranging (or securing) the chip 100 in the cavity 114, by way of example, an adhesion medium 220, e.g. a nonconductive adhesion medium (NCA/CNP), can be arranged in the cavity 114, for example by means of a needle dispenser or a nozzle. The adhesion medium can be epoxy-based, for example. The process is illustrated in FIG. 2B, for example.

In this case, the adhesion medium 220 can be partly displaced or reshaped. The adhesion medium 220 can serve for securing the chip 100 in the cavity 114. In various exemplary aspects, the adhesion medium 220 can serve to encapsulate parts of the chip 100 wetted by said adhesion medium for the purpose of protection against environmental influences, for the purpose of mechanical protection of the chip 100, and/or for the purpose of electrical insulation.

After the chip 100 has been arranged in the cavity 114, the adhesion medium 220 can be cured, for example by means of heating, e.g. using a hot plate, a furnace, a thermode, or a combination thereof.

The interconnect arrangement 102 with the chip 100 arranged in the cavity 114 is illustrated by way of example in FIG. 2C. Adhesion medium 220 displaced from the bottom of the cavity 114 has penetrated into a gap between side surfaces of the substrate 120 and side surfaces of the chip 100 and partially or completely covers the bottom of the cavity. At a top side, the adhesion medium 220 in the gap can form a fillet.

The chip-interconnect arrangement 200 can furthermore comprise an electrically conductive adhesion medium 222, which electrically connects the at least one chip contact 108 to the interconnect 116.

In a case in which more than one chip contact 108 (e.g. C-LA and C-LB) is provided, and the interconnect 116 comprises more than one contact (e.g. two antenna contacts LA and LB), each of the chip contacts C-LA, C-LB can be or have been electrically conductively connected to one of the contacts of the interconnect 116 (e.g. one of the antenna contacts LA, LB).

The adhesion medium 222 can firstly have been or be arranged between the contacts 108, 116 to be connected, for example on the (fillet-shaped) adhesion medium 220. That is illustrated by way of example in FIG. 2D. One portion of the adhesion medium 222 is arranged between the chip contact 108 C-LA and the interconnect contact 116, LA, and a second portion of the adhesion medium 222 is arranged between the chip contact 108, C-LA and the interconnect contact 116, LA.

The adhesion medium 222 can subsequently be reshaped (for example pressed flat) such that the adhesion medium 222 comprises a planar surface. A surface area used to exert a force for reshaping the adhesion medium 222 can be planar or substantially planar. This planarity can be transferred to the adhesion medium 222 during reshaping.

During the reshaping, the chip-interconnect arrangement 200 can typically be arranged such that it bears by a (rear) side facing away from the chip 100 on a planar surface (which can be oriented horizontally, for example). After the reshaping, the surface of the adhesion medium 222 can be parallel or substantially parallel to the planar surface, and can likewise be parallel or substantially parallel to a plane defined by bearing points of the rear side of the chip-interconnect arrangement 200.

Furthermore, the chip contact surface, the interconnect surface and the surface of the adhesion medium 222 can be coplanar with respect to one another or the surface of the adhesion medium can be coplanar with respect to that surface out of the chip contact surface and the antenna surface which is further away from a principal plane of the substrate. Pressing flat can be effected by means of a hot thermode, for example. The adhesion medium 222 can also be cured at the same as being pressed flat. In the case of an antenna extending over two main surfaces, the interconnect surface refers, of course, to the surface arranged over that main surface of the substrate 120 on which the chip contact surface is also exposed.

During pressing flat and before curing, the heated adhesion medium 222 can flow, for example in a direction parallel to the chip edge and in a direction perpendicular to the chip edge, and can at the latest here come into contact both with the closest chip contact 108 and with the closest interconnect contact 116, and decrease its height, for example to the same height as the higher of the two surfaces.

In various exemplary aspects, the adhesion medium 222 can be coplanar with that surface (of the chip contact 108 or of the interconnect contact 116) which is further away from a central plane of the chip arrangement (i.e. with the surface situated at a higher level). The adhesion medium 222 can at least partly cover the other surface (i.e. out of the surfaces 108, 116 the one situated at a lower level).

The result of the reshaping process is illustrated by way of example in FIG. 2E.

In the exemplary aspect from FIG. 2E it is evident, for example on the basis of the adhesion medium 222 extending exactly along the edge of the respective contact 116, that the surface of the interconnect contact 116, LA and respectively 116, LB is in each case the surface situated at a higher level. The surface of the chip contact 108 situated at a lower level is partly covered by the electrically conductive adhesion medium 222.

In the case of the electrically conductive adhesion medium 222, it may be sufficient that to a degree the adhesion medium adheres to itself and to materials with which the adhesion medium 222 is in contact in order to bridge the gap between the contacts 208, 116 to be connected and to create a permanent electrically conductive connection (solders known from the prior art typically being unable to do this). It is not necessary for the adhesion medium 222 to be suitable for securing, but it is possible, and in that case the securing function can optionally be used for (e.g. additionally) securing the chip 100 in the cavity 114. Mechanical properties of the adhesion medium 222 such as, for example, toughness, glass transition temperature Tg, modulus of elasticity, etc. can be or have been adapted in order to attain an optimum securing function and robustness. The adaptation can concern for example a base material of the adhesion medium 222 (e.g. epoxy, acrylate, etc.), which contains conductive particles (e.g. silver, nickel, gold, etc.).

Generally, the adhesion medium can comprise an isotropic electrically conductive material, for example an isotropic conductive paste (ICP) or an isotropic conductive adhesive (ICA).

In various exemplary aspects, a direct contact between the adhesion medium 222 and the chip contact 108 and/or a direct contact between the adhesion medium 222 and the interconnect contact 116 can be present only at the side surfaces of the respective contact 108, 116. In the exemplary aspect illustrated in FIG. 2E, that concerns for example the respective direct contact between the adhesion medium 222 and the interconnect contact 116, LA and/or between the adhesion medium 222 and the interconnect contact 116, LB.

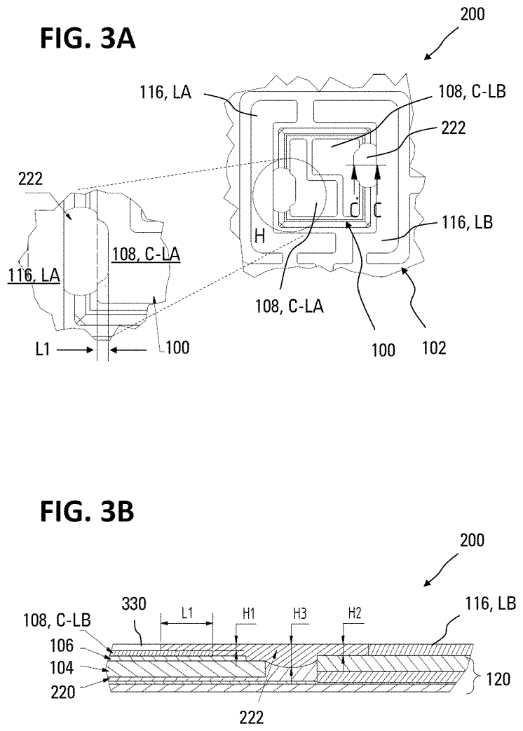

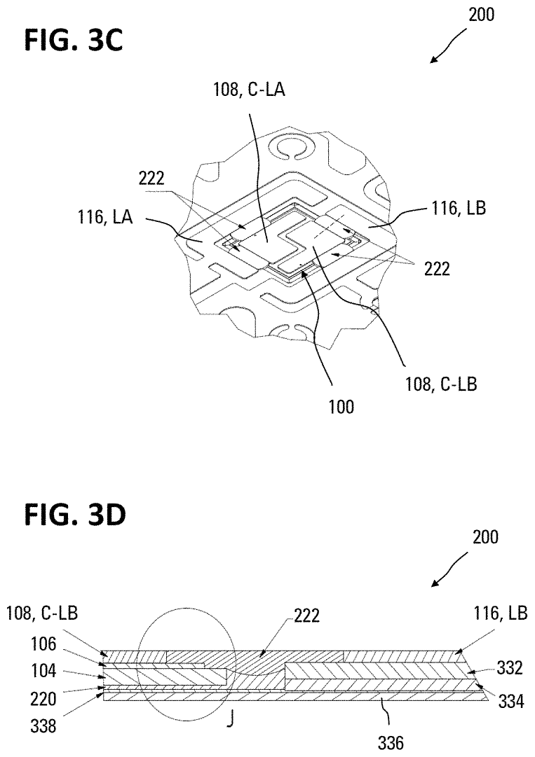

FIG. 3A to 3D each show schematic detail views of chip-interconnect arrangements 200 in accordance with various exemplary aspects.

FIG. 3A and 3C each show an enlarged illustration of a central region of a chip-interconnect arrangement 200 in accordance with various exemplary aspects, with a plan view of the chip 100 and a part of the interconnect arrangement 102. Furthermore, FIG. 3A shows an enlarged illustration of one of the regions with the adhesion medium 222. FIG. 3B is a schematic partial cross-sectional view along the line C-C from FIG. 3A. FIG. 3D is a schematic partial cross-sectional view along the dashed line from FIG. 3C. The exemplary aspect from FIG. 3A and FIG. 3B can be similar or identical to the exemplary aspect described with reference to FIG. 2A to 2E, and the exemplary aspect from FIG. 3C and FIG. 3D can be similar to that from FIGS. 2A to 2E.

In various exemplary aspects, the coplanarity of adhesion medium 222 and surface at a higher level (of the chip contact 108 or of the interconnect contact 116) or of all surfaces (adhesion medium 222, chip contact 108 and interconnect contact 116) can be endeavored to be attained since this enables the thickness of the chip-interconnect device 200 to be minimized.

In various exemplary aspects, the thickness of the chip-interconnect device 200 can be principally dependent on the thickness of the chip 100, since this thickness is less easily minimizable than for example the thickness of the substrate 120, which can be formed for example as a layer stack (with respect to FIG. 3D, by way of example, an explanation is given of what layers the substrate 120 can comprise). Accordingly, in various exemplary aspects, the thickness of the substrate 120 and the interconnect 116 can be set such that the interconnect surface is coplanar with the chip contact surface, or possibly such that the interconnect surface is the surface situated at a higher level, in particular in order to prevent more pressure from being exerted on the chip 100 than on the interconnect arrangement 102 during the reshaping process, or in order to achieve the effect that during the reshaping process pressure (e.g. by means of the thermode) is exerted principally on the relatively insensitive interconnect arrangement 102, and not on the more pressure-sensitive chip 100.

In the exemplary aspect illustrated in FIGS. 3A and 3B, the interconnect surface is the surface situated at a higher level, and the adhesion medium 222 is coplanar with the interconnect surface. A height difference H1 between the interconnect surface and the chip contact surface can be kept as small as possible, for example smaller than 10 μm, for example smaller than approximately 5 μm. During the reshaping process, the adhesion medium 222 can be partly pressed onto the chip contact surface situated at a lower level and form an overlap region. The overlap region typically does not make an appreciable contribution to the conductivity of the contact, rather said conductivity is principally provided by way of the side surfaces. In the case of a height difference H1 of less than 5 μm, it is even possible for the overlap region to contain only few or no conductive particles, but rather only carrier material, e.g. epoxy.

An additional protective layer 330, e.g. an organic or inorganic coating, can be arranged on the chip contact 108, for example in order to protect the chip contact-adhesion medium transition region.

A geometry of the chip-interconnect arrangement 200 and reshaping parameters such as pressure and temperature and flow properties of the adhesion medium 222 at the reshaping temperature can have been or be set such that an overlap width L1 between an edge of the chip contact 108 and an edge of the adhesion medium 222 at the point at which it has advanced the furthest toward the chip contact 108 does not exceed a predefined limit value or is even minimized. In this case, it is possible in particular to ensure that the adhesion medium 222 comes into contact only with the chip contact C-LA or C-LB (or interconnect contact LA or LB) to be contacted, and not additionally with the respective other contact.

The overlap width L1 can become larger with a larger height difference H1. In order to keep L1 small, a cross section of the gap (which can form a flow channel for the heated adhesion medium 222) can be large in comparison with the height difference H1. For example, a height H3 of the gap can be very much larger than the height difference, and a thickness H2 of the contact situated at a higher level (the interconnect contact 116 in FIG. 3B) can be larger than the height difference H1. This can achieve the effect that the adhesion medium 222 flows or is redistributed principally parallel to the chip edge, and thus perpendicular to L1.

In the exemplary aspect illustrated in FIGS. 3C and 3D, the adhesion medium 222 is coplanar both with the chip surface and with the interconnect surface.

Accordingly, the adhesion medium 222 extends only along the gap between the interconnect 116 and the chip contact 108, and not onto one of the surfaces.

FIG. 3C additionally shows that per interconnect contact/chip contact pairing, the adhesion medium 222, which electrically conductively connects them to one another, can be arranged at more than one point. In the exemplary aspect, the adhesion medium 222 for each pairing is arranged across two different chip edges. In this context, in each case one point of the adhesion medium 222 is in contact with the long limb of the L-shaped chip contact 108 and the other point of the adhesion medium 222 is in contact with the short limb of the L-shaped chip contact 108. The L-shape fosters the arrangement of the adhesion medium at a plurality of points because even the short limb (compared with a rectangular chip contact 108, for example, which at its narrow end would be shorter than half a chip width) is long enough that during the reshaping of the adhesion medium 222 it is possible to ensure that an undesired contact with the other chip contact 108 and thus a short circuit do not occur.

The substrate 120 can comprise for example the (e.g. polymer) carrier tape 332, a rear-side metallization 334 and a rear-side substrate 336 (for example likewise a polymer) attached by means of an adhesion medium 338.

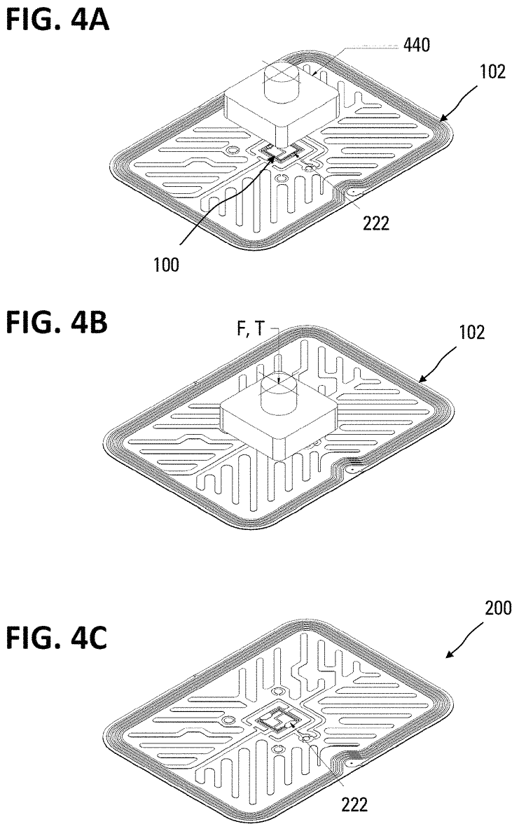

FIGS. 4A to 4C elucidate the method for forming a chip-interconnect arrangement 200, in accordance with various exemplary aspects, in particular the reshaping process that has already been explained above with reference to FIGS. 2D and 2E.

In FIG. 4A, the adhesion medium 222 is arranged at two points in each case between two contacts to be connected, namely in each case between a chip contact 108 and an assigned interconnect contact 116 (e.g. between 108, C-LA and 116, LA and between 108, C-LB and 116, LB).

FIG. 4B illustrates the reshaping process, in which a force F and heat corresponding to a temperature T are transferred to the chip-interconnect arrangement 200 by means of a thermode 440 in order to reshape the adhesion medium 222 (e.g. press it flat) until it is coplanar at least with the uppermost surface out of the interconnect surface and the chip contact surface (this being the interconnect surface here). The force F or the pressing-on pressure generated as a result can be set such that when a predetermined maximum pressing-on pressure is attained, the thermode 440 is in direct contact with the surface situated at a higher level (the interconnect surface in this case), such that no adhesion medium 222 remains between the thermode 440 and the surface situated at a higher level (or both surfaces if the interconnect surface and the chip contact surface are coplanar).

In order to prevent the thermode 440 from being contaminated by the adhesion medium 222, said thermode can be covered with a removable protective layer, for example with a silicone- or Teflon-coated paper. The protective layer can for example be provided in the form of a tape and be moved further between two successive reshaping processes, such that a new, uncontaminated region of the protective layer can be used for each reshaping process.

FIG. 4C shows the produced chip-interconnect arrangement 200 with the reshaped adhesion medium 222, which is coplanar with the interconnect surface.

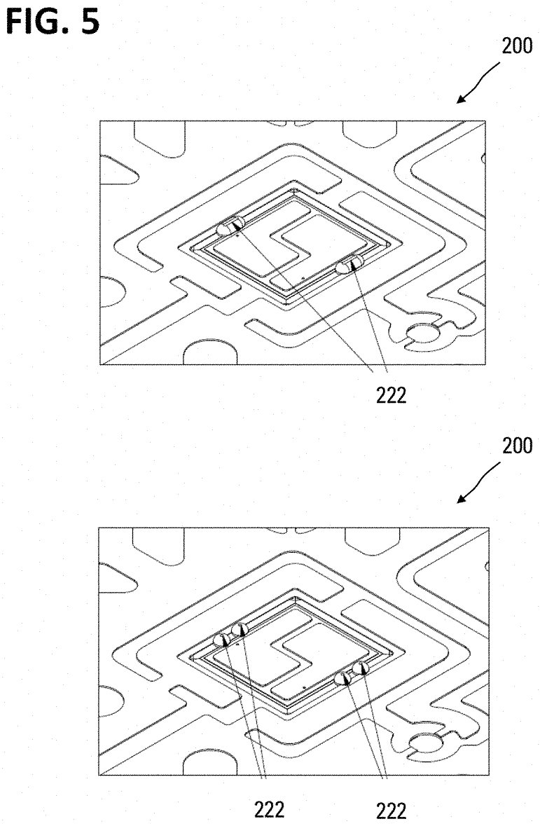

FIG. 5 shows schematic detail views of a process for producing chip-interconnect arrangements 200 in accordance with various exemplary aspects, in particular of application of the adhesion medium 222 prior to reshaping. The adhesion medium 222, for example depending on its flow properties and the geometry of the chip-interconnect arrangement 200, can be applied as a single (e.g. larger) reservoir (upper illustration) or as a plurality of (e.g. smaller) reservoirs.

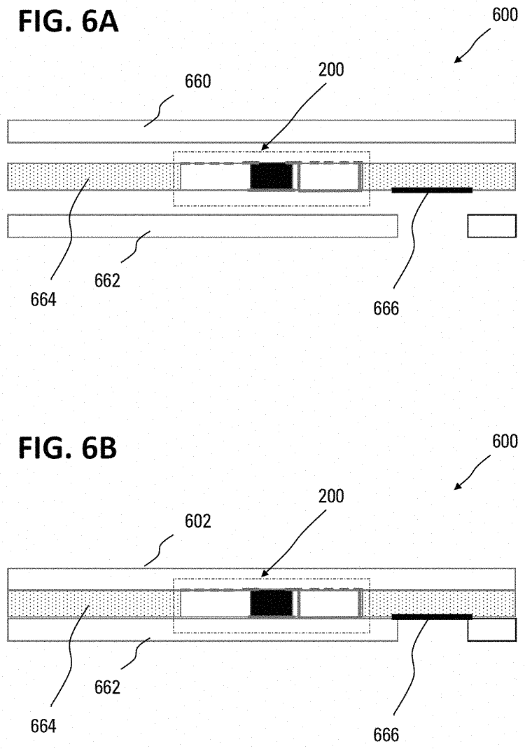

FIG. 6A shows an exploded drawing of a document structure 600 in accordance with various exemplary aspects, and FIG. 6B shows a schematic illustration of the document structure 600 from FIG. 6A.

As already indicated above, the chip-interconnect arrangement 200 can be provided for being introduced into a very thin document structure 600.

The chip-interconnect arrangement 200 can be arranged, for example laminated in, for example between a first paper layer 660 and a second paper layer 662.

In various examples, the chip-interconnect arrangement 200 can be arranged in a cavity of a carrier layer 664.

A security feature 666 can additionally be arranged on the carrier layer 664. If the security feature 666 is provided for optical perception, the overlying (here the second) paper layer 662 can be provided with a viewing opening.

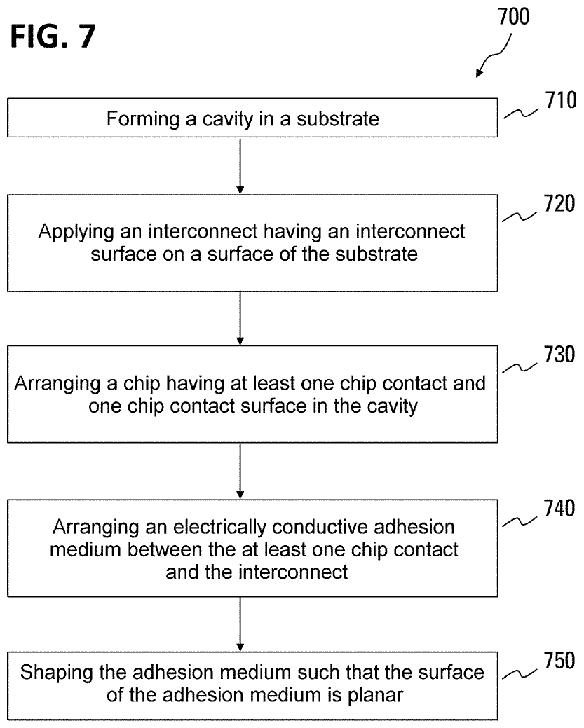

FIG. 7 shows a flow diagram 700 of a method for forming a chip-interconnect arrangement according to various aspects.

The method comprises forming a cavity in a substrate (710), applying an interconnect having an interconnect surface on the surface of the substrate (720), arranging a chip having at least one chip contact and one chip contact surface in the cavity (730), arranging an electrically conductive adhesion medium between the at least one chip contact and the interconnect (740), and shaping the adhesion medium such that the surface of the adhesion medium is planar (750).

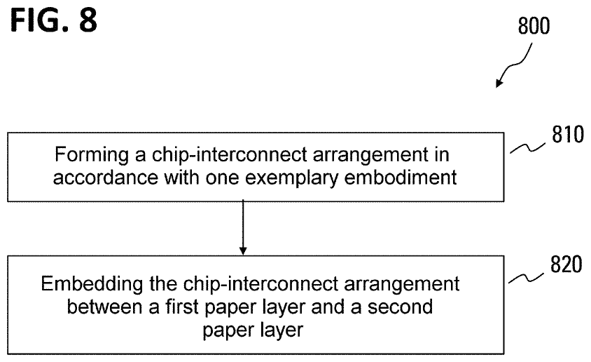

FIG. 8 shows a flow diagram 800 of a method for forming a document structure according to various exemplary aspects.

The method comprises forming a chip-interconnect arrangement in accordance with one of the exemplary aspects (810), for example as described in association with FIG. 7 and/or with FIGS. 2A to 2E, and embedding the chip-interconnect arrangement between a first paper layer and a second paper layer (820).

Some exemplary aspects are specified in summary below.

Exemplary aspect 1 is a chip-interconnect arrangement, comprising a substrate having a cavity, a chip having at least one chip contact and one chip contact surface, such chip being arranged in the cavity, an interconnect having an interconnect surface, said interconnect being applied on a surface of the substrate, and an electrically conductive adhesion medium, which electrically connects the at least one chip contact to the interconnect, wherein the surface of the adhesion medium is planar.

Exemplary aspect 2 is a chip-interconnect arrangement in accordance with exemplary aspect 1, wherein when the chip-interconnect arrangement bears on a horizontal surface with a chip facing away from the surface, the planar surface of the adhesion medium is substantially parallel to the horizontal surface.

Exemplary aspect 3 is a chip-interconnect arrangement in accordance with exemplary aspect 1 or 2, wherein the chip contact surface, the interconnect surface and a surface of the adhesion medium are coplanar with respect to one another or the adhesion medium is coplanar with respect to that surface out of the chip contact surface and the interconnect surface which is further away from a principal plane of the substrate.

Exemplary aspect 4 is a chip-interconnect arrangement in accordance with any of exemplary aspects 1 to 3, wherein the adhesion medium comprises an isotropic conductive adhesive.

Exemplary aspect 5 is a chip-interconnect arrangement in accordance with any of exemplary aspects 1 to 4, wherein the interconnect comprises an antenna.

Exemplary aspect 6 is a chip-interconnect arrangement in accordance with any of exemplary aspects 1 to 4, wherein the adhesion medium is coplanar with the interconnect surface.

Exemplary aspect 7 is a chip-interconnect arrangement in accordance with any of exemplary aspects 1 to 4, wherein the adhesion medium partially covers the chip contact surface or the interconnect surface in a coverage region, wherein a thickness of the adhesion medium in the coverage region comprises maximally 10 μm, optionally maximally 5 μm.

Exemplary aspect 8 is a chip-interconnect arrangement in accordance with any of exemplary aspects 1 to 7, wherein the chip comprises a plurality of edges which form a polygon (typically a rectangle, for example a square), wherein an individual chip contact of the at least one chip contact extends along at least two edges.

Exemplary aspect 9 is a chip-interconnect arrangement in accordance with exemplary aspect 8, wherein the adhesion medium contacts the individual chip contact across at least one of the two edges.

Exemplary aspect 10 is a chip-interconnect arrangement in accordance with any of exemplary aspects 1 to 9, wherein the adhesion medium is shaped by means of pressure and/or heat.

Exemplary aspect 11 is a chip-interconnect arrangement in accordance with any of exemplary aspects 1 to 10, wherein the at least one chip contact comprises an L-shape.

Exemplary aspect 12 is a chip-interconnect arrangement in accordance with any of exemplary aspects 1 to 11, wherein the chip-interconnect arrangement comprises a thickness of a maximum of 80 μm.

Exemplary aspect 13 is a chip-interconnect arrangement in accordance with any of exemplary aspects 1 to 12, wherein the chip is a security chip.

Exemplary aspect 14 is a document structure, comprising a first paper layer, a second paper layer, and a chip-interconnect arrangement in accordance with any of exemplary aspects 1 to 13 between the first paper layer and the second paper layer.

Exemplary aspect 15 is a method for forming a chip-interconnect arrangement, wherein the method comprises forming a cavity in a substrate, applying an interconnect having an interconnect surface on a surface of the substrate, arranging a chip having at least one chip contact and one chip contact surface in the cavity, arranging an electrically conductive adhesion medium between the at least one chip contact and the interconnect, and shaping the adhesion medium such that the surface of the adhesion medium is planar.

Exemplary aspect 16 is a method in accordance with exemplary aspect 15, wherein when the chip-interconnect arrangement bears on a horizontal surface with a chip facing away from the surface, the planar surface of the adhesion medium is substantially parallel to the horizontal surface.

Exemplary aspect 17 is a chip-interconnect arrangement in accordance with exemplary aspect 15 or 16, wherein the chip contact surface, the interconnect surface and a surface of the adhesion medium are coplanar with respect to one another or the adhesion medium is coplanar with respect to that surface out of the chip contact surface and the interconnect surface which is further away from a principal plane of the substrate.

Exemplary aspect 18 is a method in accordance with any of exemplary aspects 15 to 17, wherein the adhesion medium comprises an isotropic conductive adhesive.

Exemplary aspect 19 is a method in accordance with any of exemplary aspects 15 to 18, wherein the shaping comprises pressing the adhesion medium flat.

Exemplary aspect 20 is a method in accordance with any of exemplary aspects 17 to 19, wherein the adhesion medium is coplanar with the interconnect surface.

Exemplary aspect 21 is a method in accordance with any of exemplary aspects 17 to 19, wherein the adhesion medium partially covers the chip contact surface or the interconnect surface in a coverage region, wherein a thickness of the adhesion medium in the coverage region comprises maximally 10 μm, optionally maximally 5 μm.

Exemplary aspect 22 is a method in accordance with any of exemplary aspects 17 to 21, wherein the chip comprises a plurality of edges which form a polygon (typically a rectangle, for example a square), wherein an individual chip contact of the at least one chip contact extends along at least two edges.

Exemplary aspect 23 is a method in accordance with exemplary aspect 22, wherein the adhesion medium contacts the individual chip contact across at least one of the two edges.

Exemplary aspect 24 is a method in accordance with any of exemplary aspects 17 to 23, wherein the shaping comprises applying pressure and/or heat.

Exemplary aspect 25 is a method in accordance with any of exemplary aspects 17 to 24, wherein the at least one chip contact comprises an L-shape.

Exemplary aspect 26 is a method in accordance with any of exemplary aspects 17 to 25, wherein the chip-interconnect arrangement comprises a thickness of a maximum of 80 μm.

Exemplary aspect 27 is a method in accordance with any of exemplary aspects 17 to 26, wherein the chip is a security chip.

Exemplary aspect 28 is a method for forming a document structure, which method comprises forming a chip-interconnect arrangement in accordance with any of exemplary aspects 17 to 27 and embedding the chip-interconnect arrangement between a first paper layer and a second paper layer.

Exemplary aspect 29 is a method in accordance with exemplary aspect 28, wherein the embedding comprises laminating.

Further advantageous configurations of the device are evident from the description of the method, and vice versa.

1. A chip-interconnect arrangement, comprising:
a substrate having a cavity;
a chip having at least one chip contact and one chip contact surface, the chip being arranged in the cavity;
an interconnect having an interconnect surface, the interconnect being applied on a surface of the substrate; and
an electrically conductive adhesion medium, which electrically connects the at least one chip contact to the interconnect,
wherein the adhesion medium comprises a planar surface.

2. The chip-interconnect arrangement as claimed in claim 1,
wherein when the chip-interconnect arrangement bears on a horizontal surface with a chip facing away from the surface, and the planar surface of the adhesion medium is substantially parallel to the horizontal surface.

3. The chip-interconnect arrangement as claimed in claim 1,
wherein the chip contact surface, the interconnect surface and a surface of the adhesion medium are coplanar with respect to one another or the adhesion medium is coplanar with respect to that surface out of the chip contact surface and the interconnect surface which is further away from a principal plane of the substrate.

4. The chip-interconnect arrangement as claimed in claim 1,
wherein the adhesion medium has an isotropic conductive adhesive.

5. The chip-interconnect arrangement as claimed in claim 1,
wherein the interconnect has an antenna.

6. The chip-interconnect arrangement as claimed in claim 1,
wherein the adhesion medium is coplanar with the interconnect surface.

7. The chip-interconnect arrangement as claimed in claim 1,
wherein the chip comprises a plurality of edges which form a polygon, and
wherein an individual chip contact of the at least one chip contact extends along at least two edges.

8. The chip-interconnect arrangement as claimed in claim 7,
wherein the adhesion medium contacts the individual chip contact across at least one of the two edges.

9. The chip-interconnect arrangement as claimed in claim 1,
wherein the at least one chip contact comprises an L-shape.

10. The chip-interconnect arrangement as claimed in claim 1, wherein the chip-interconnect arrangement comprises a thickness of a maximum of 80 μm.

11. The chip-interconnect arrangement as claimed in claim 1,
wherein the chip is a security chip.

12. A document structure, comprising:
a first paper layer;
a second paper layer; and
a chip-interconnect arrangement as claimed in claim 1 between the first paper layer and the second paper layer.

13. A method for forming a chip-interconnect arrangement, the method comprising:
forming a cavity in a substrate;
applying an interconnect having an interconnect surface on a surface of the substrate;
arranging a chip having at least one chip contact and one chip contact surface in the cavity;
arranging an electrically conductive adhesion medium between the at least one chip contact and the interconnect; and
shaping the adhesion medium such that the surface of the adhesion medium is planar.

14. The method as claimed in claim 13,
wherein when the chip-interconnect arrangement bears on a horizontal surface with a chip facing away from the surface, and a planar surface of the adhesion medium is substantially parallel to the horizontal surface.

15. The method as claimed in claim 13,
wherein the chip contact surface, the interconnect surface and a surface of the adhesion medium are coplanar with respect to one another or the adhesion medium is coplanar with respect to that surface out of the chip contact surface and the interconnect surface which is further away from a principal plane of the substrate.

16. The method as claimed in claim 13,
wherein the shaping comprises pressing the adhesion medium flat.

17. The method as claimed in claim 13,
wherein the shaping comprises applying pressure and/or heat.

18. A method for forming a document structure, comprising:
forming a chip-interconnect arrangement as claimed in claim 13; and
embedding the chip-interconnect arrangement between a first paper layer and a second paper layer.

19. The method as claimed in claim 18,
wherein the embedding comprises laminating.
